(19) United States
(12) Patent Application Publication
(10) Pub. No.: US 2026/0068406 A1
(43) Pub. Date: Mar. 5, 2026

(54) LIGHT BEAD, LIGHT PLATE, AND DISPLAY DEVICE

(71) Applicant: HKC CORPORATION LIMITED, Shenzhen (CN)

(72) Inventors: Hongsong Wang, Shenzhen (CN); Bo Zhang, Shenzhen (CN); Kunpeng Yang, Shenzhen (CN); Xinye Lv, Shenzhen (CN); Liming Jiang, Shenzhen (CN); Lidan Ye, Shenzhen (CN)

(21) Appl. No.: 19/304,463

(22) Filed: Aug. 19, 2025

(30) Foreign Application Priority Data
Sep. 2, 2024 (CN) 202411216532.9

(51) Int. Cl. H10H 29/855; H10H 29/49; H10H 29/85; H10H 29/851

(52) U.S. Cl. CPC H10H 29/855; H10H 29/49; H10H 29/8512; H10H 29/8517

(57) ABSTRACT

A light bead, a light plate, and a display device are disclosed. The light bead includes a light bead main body, a buffer portion, and a mating portion. The light bead main body includes a first end and a second end that are spaced apart from each other. The first end is the end of the light bead main body adjacent to a light-emitting side. The second end is the end of the light bead main body opposite to the light-emitting side. The buffer portion is arranged on the first end of the light bead main body and fits around the first end of the light bead main body. The mating portion is arranged on the second end of the light bead main body and is configured to mate with the light plate to install the light bead onto the light plate.

### CROSS-REFERENCE TO RELATED APPLICATIONS

This application claims the priority and benefit of Chinese patent application number 2024112165329, titled “Light Bead, Light Plate, and Display Device” and filed Sep. 2, 2024 with China National Intellectual Property Administration, the entire contents of which are incorporated herein by reference.

### TECHNICAL FIELD

The present application relates to the field of mass transfer technology, and more particularly relates to a light bead, a light plate, and a display device.

### BACKGROUND

The description provided in this section is intended for the mere purpose of providing background information related to the present application but does not necessarily constitute prior art.

With the development of display technology, the fabrication process of miniaturized components has become a trend of development in display panels, such as Micro-Light Emitting Diode (LED), also known as Micro-LED technology. Micro-Light Emitting Diodes (Micro-LEDs) have self-emissive display characteristics, and their advantages include all-solid-state structure, long lifespan, high brightness, low power consumption, small size, ultra-high resolution, and applicability in extreme environments such as high temperatures or radiation. Compared with Organic Light-Emitting Diode (OLED) technology, which is also self-emissive, Micro-LEDs not only have higher efficiency and longer lifespan, but their materials are relatively stable and less affected by the environment, and they can also avoid issues such as image retention.

However, the mass transfer of Micro-LED chips is a key challenge in the manufacturing process. Due to the extremely small size of Micro-LED chips, mass transfer requires very high efficiency, yield, and transfer accuracy. Therefore, mass transfer technology has become the greatest technical challenge in the manufacturing process of Micro-LED panels, hindering the promotion and application of Micro-LED technology.

Therefore, providing a light bead, light plate, and display device that can achieve mass transfer of chips while also realizing precise alignment to improve mass transfer efficiency and simplify the manufacturing process is a technical problem urgently to be solved by those skilled in the art.

### SUMMARY

It is therefore one purpose of the present application to provide a light bead, light plate, and display device that, by setting a buffer portion, prevents the light bead from rotating or flipping, thereby avoiding impacts on the installation accuracy of the light bead and achieving precise alignment of the light bead during mass transfer.

The present application discloses a light bead, which is applied to a light plate. The light bead includes a light bead main body, a buffer portion, and a mating portion. The light bead main body includes a first end and a second end that face away from each other. The first end is the end of the light bead main body that is close to the light-emitting side. The second end is the end of the light bead main body facing away from the light-emitting side. The buffer portion is disposed on the first end of the light bead main body. The buffer portion is arranged to fit around the first end of the light bead main body. The mating portion is disposed on the second end of the light bead main body. The mating portion is configured to mate with the light plate to install the light bead onto the light plate. During installation of the light bead, the buffer portion provides resistance to the light bead, so that the light bead is installed at the corresponding position on the light plate.

In some embodiments, the buffer portion is a reflective sheet, and the reflective sheet is arranged to fit around the first end of the light bead main body.

In some embodiments, the light bead main body further includes a counterweight portion, and the counterweight portion is disposed between the first end and the second end. The mass of the counterweight portion near the outer side of the light bead main body is greater than the mass of the counterweight portion near the center of the light bead main body.

In some embodiments, an electrode layer is further disposed on the second end of the light bead main body, and the electrode layer is connected to the light plate.

In some embodiments, the light bead further includes a grounding pillar, which is disposed on the second end of the light bead main body.

In some embodiments, the light bead further includes a light-emitting chip and a color filter layer. The light-emitting chip is disposed inside the light bead main body. The color filter layer is disposed on the side of the light-emitting chip adjacent to the first end of the light bead main body. Light emitted from the light-emitting chip passes through the color filter layer to form light of the same or different colors. The color filter layer includes a first color region, a second color region, and a third color region having the same area. Light emitted from the light-emitting chip is converted into first color light when passing through the first color region. Light emitted from the light-emitting chip is converted into second color light when passing through the second color region. Light emitted from the light-emitting chip is converted into third color light when passing through the third color region.

In some embodiments, the light bead further includes an encapsulation layer, the encapsulation layer being disposed on the side of the color filter layer facing away from the light-emitting chip. The buffer portion is disposed on the side of the encapsulation layer facing away from the center of the light bead main body.

The present application also discloses a light plate applied to a display panel. The light plate includes a bottom plate, a magnetic attraction layer, a planarization layer, a power supply layer, and a plurality of the above-mentioned light beads. The magnetic attraction layer is disposed on the bottom plate. The planarization layer is disposed on the magnetic attraction layer. A plurality of mounting slots are formed on the planarization layer and the magnetic attraction layer. The power supply layer is disposed at a bottom of each of the mounting slots. The light bead is installed in the mounting slot. When the light bead is installed onto the mounting slot, the power supply layer provides power to the light bead.

In some embodiments, the light plate further includes a sealant frame, which is disposed on the bottom plate and located around the periphery of the bottom plate.

The present application also discloses a display device, including a display panel and a driving circuit. The display panel includes the light plate as described above. The driving circuit is configured to drive the display panel.

The light bead of the present application provides a buffer portion, which offers resistance to the light bead during its downward falling process, thereby increasing the stability of the light bead during mass transfer, better resisting external disturbances during the mass transfer process, preventing rotation or flipping of the light bead during falling that would affect the installation accuracy, achieving precise positioning of the light bead during mass transfer, and improving the efficiency of mass transfer.

### BRIEF DESCRIPTION OF DRAWINGS

The accompanying drawings are used to provide a further understanding of the embodiments according to the present application, and constitute a part of the specification. They are used to illustrate the embodiments according to the present application, and explain the principles of the present application in conjunction with the text description. Apparently, the drawings in the following description merely represent some embodiments of the present disclosure, and for those having ordinary skill in the art, other drawings may also be obtained based on these drawings without investing creative. In the drawings:

FIG. 1 is a schematic diagram of the overall structure of a light bead according to a first embodiment of the present application.

FIG. 2 is a top view schematic diagram of a light bead according to the first embodiment of the present application.

FIG. 3 is a schematic diagram of a light plate according to a second embodiment of the present application.

FIG. 4 is a schematic diagram of a light plate with light beads installed according to the second embodiment of the present application.

FIG. 5 is a schematic diagram of the overall structure of the light plate according to the second embodiment of the present application.

FIG. 6 is a schematic diagram of a display device according to a third embodiment of the present application.

FIG. 7 is a chart of bending resistance test data of a bottom plate of the present application.

In the drawings: 100, light bead; 110, light bead main body; 111, counterweight portion; 120, buffer portion; 130, mating portion; 140, electrode layer; 150, grounding pillar; 160, light-emitting chip; 170, color filter layer; 171, first color region; 172, second color region; 173, third color region; 180, encapsulation layer; 200, light plate; 210, bottom plate; 220, magnetic attraction layer; 230, planarization layer; 231, mounting slot; 240, power supply layer; 250, sealant frame; 261, lower diffusion layer; 262, lower prism layer; 263, upper prism layer; 264, upper diffusion layer; 265, glass substrate; 300, display panel; 400, driving circuit; 500, display device.

### DETAILED DESCRIPTION OF EMBODIMENTS

It should be understood that the terms used herein, the specific structures and functional details disclosed therein are merely representative for describing some specific embodiments, but the present application can be implemented in many alternative forms and should not be construed as being limited to only these embodiments described herein.

As used herein, terms “first”, “second”, or the like are merely used for illustrative purposes, and shall not be construed as indicating relative importance or implicitly indicating the number of technical features specified. Thus, unless otherwise specified, the features defined by “first” and “second” may explicitly or implicitly include one or more of such features. Terms “multiple”, “a plurality of”, and the like mean two or more. Terms “comprise”, “comprising”, “includes”, “including”, and any variations thereof are intended to be non-exclusive, and one or more other features, integers, steps, operations, units, components, and/or combinations thereof may be present or be added.

In addition, terms “center” “lateral”, “up”, “down”, “left”, “right”, “vertical”, and “horizontal”, “top”, “bottom”, “inside”, or the like are used to indicate orientational or relative positional relationships based on those illustrated in the drawings. They are merely intended for simplifying the description of the present disclosure, rather than indicating or implying that the device or element referred to must have a particular orientation or be constructed and operate in a particular orientation. Therefore, these terms are not to be construed as restricting the present disclosure.

In addition, unless otherwise clearly specified and defined, the terms “installed on”, “disposed on”, “arranged on”, and “connected to” should be understood in a broad sense. For example, it may be a fixed connection, a detachable connection, or an integral connection; it may be a mechanical connection or an electrical connection; it may be a direct connection or an indirect connection through an intermediate medium, or it may be internal communication between two elements. For those of ordinary skill in the art, the specific meanings of the above terms as used in the present application can be understood depending on specific contexts.

The present application is described in detail below with reference to the accompanying drawings and optional embodiments. It should be noted that, under the premise of no conflict, the embodiments or technical features described below can be arbitrarily combined to form new embodiments.

The inventor(s) of the present application discovered during the assembly process of Micro-LED displays that the requirements for mass transfer of light beads onto the light plate are extremely high, which constitutes a significant technical challenge. If mass transfer errors or misalignments occur, manual repositioning is required to adjust the light beads. Especially in the related light bead mounting process that achieves mass transfer by dropping, due to the light bead's own light weight (because of its small size), it may rotate or flip during the falling installation process, which affects the mounting accuracy of the light bead and results in unsuccessful mass transfer. When new types of counterweights or added weights are added to the light bead, the light bead must be dropped from a relatively high height during installation to maintain its posture. Furthermore, the counterweights or added weights may need to be peeled off and removed after installation, which increases the steps of the mass transfer process and is very inconvenient. Under these circumstances, the inventors redesigned the structures of the light bead and light plate to arrive at the technical solution of the present application, with the specific details as follows.

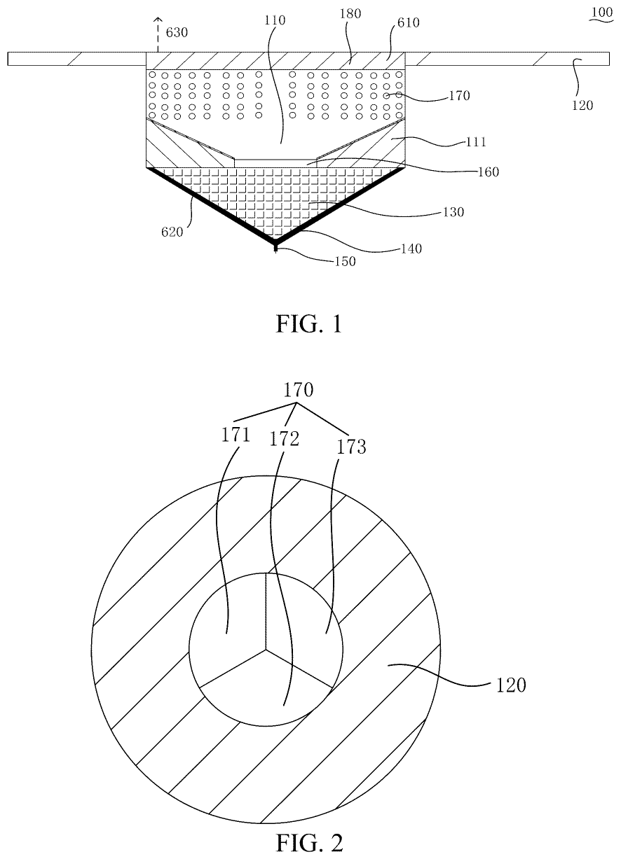

As shown in FIG. 1, a light bead 100 is disclosed as a first embodiment of the present application. The light bead 100 is applied to a light plate 200. The light bead 100 includes a light bead main body 110, a buffer portion 120, and a mating portion 130. The light bead main body 110 includes a first end 610 and a second end 620 that are mutually spaced apart. The first end 610 is the end of the light bead main body 110 close to the light-emitting side 630. The second end 620 is the end of the light bead main body 110 facing away from the light-emitting side 630. The buffer portion 120 is arranged on the first end 610 of the light bead main body 110. The buffer portion 120 is disposed to enclose the first end 610 of the light bead main body 110. The mating portion 130 is arranged on the second end 620 of the light bead main body 110. The mating portion 130 is fitted with the light plate 200 to install the light bead 100 onto the light plate 200. When the light bead 100 is being installed, the buffer portion 120 provides resistance to the light bead 100, so that the light bead 100 is installed at the corresponding position on the light plate 200.

The term “encloses” in the configuration where the buffer portion 120 encloses the first end 610 of the light bead main body 110 means that the buffer portion 120 is arranged around the periphery of the first end 610 of the light bead main body 110. For example, the buffer portion 120 may be a sheet-shaped buffer material with a circular hole in the center, and the shape of the circular hole is roughly the same as that of the first end 610 of the light bead main body 110. Thus, the circular hole in the middle of the buffer portion 120 can fit around the periphery of the first end 610 of the light bead main body 110, thereby surrounding or enclosing the periphery of the first end 610 of the light bead main body 110. Of course, the shape of the circular hole in the middle of the buffer portion 120 or the shape of the first end 610 of the light bead main body 110 described here is provided merely as an example, and their shapes are not limited to the ones described above. In practice, these shapes may vary and can take other forms, as long as the shape of the hole in the buffer portion 120 substantially corresponds to the shape of the first end 610 of the light bead main body 110.

Then, when the circular hole in the center of the buffer portion 120 fits around the periphery of the first end 610 of the light bead main body 110, they can be connected together by adhesive bonding or other connection methods. Alternatively, without using adhesive, they can also be secured directly by an interference fit.

In other embodiments, the buffer portion 120 may not have a central hole, but instead be a complete sheet-shaped material. In such cases, the buffer portion 120 can be directly bonded or otherwise fixed to the first end 610 of the light bead main body 110, as long as the buffer portion 120 and the first end 610 of the light bead main body 110 are fixed to each other securely.

In this embodiment, during mass transfer, the light bead 100 can be positioned directly above the corresponding installation location on the light plate 200. The light bead 100 falls relying on its own weight. During this process, because the buffer portion 120 encloses the first end 610 of the light bead main body 110, the buffer portion 120 provides resistance to the light bead 100 as it falls, preventing rotation or flipping that could affect the mounting accuracy of the light bead 100. This allows the light bead 100 to achieve precise alignment during mass transfer, thereby improving mass transfer efficiency. Compared to related methods where the light bead 100 simply falls, this embodiment provides resistance via the buffer portion 120 during the fall to prevent rotation or flipping that would affect installation precision. Furthermore, compared to related solutions that add new counterweights or additional weights on the light bead 100, in this embodiment, the light bead 100 can fall from a lower height. The buffer portion 120 provides resistance to improve the mounting accuracy of the light bead 100. After installation, the process can proceed directly to the next step without requiring removal of any added weights or counterweights, thus avoiding additional mass transfer steps. Overall, by setting the buffer portion 120, this embodiment increases the stability of the light bead 100 during mass transfer, better resisting external disturbances during the process, preventing rotation or flipping during the fall that could affect installation accuracy, and achieving precise alignment in mass transfer, thereby improving transfer efficiency. The mating portion 130 may be a magnetic attraction structure, and a corresponding magnetic attraction layer 220 arranged on the light plate 200 can assist in completing the installation of the light bead 100.

The inventor(s) of this application also considered that although adding the buffer portion 120 on the light bead 100—where the buffer portion 120 encloses the first end 610 of the light bead main body 110—improves the mounting accuracy of the light bead 100 during mass transfer, after the light bead 100 is installed on the light plate 200, the buffer portion 120 affects the spacing between the light beads 100. Consequently, a certain gap is required between the light beads 100, which may cause inconsistencies in light intensity across different areas of the light plate 200 during illumination. Therefore, the inventor(s) configured the buffer portion 120 as a reflective sheet, which encloses the first end 610 of the light bead main body 110. Thus, after the light bead 100 is installed on the light plate 200, as shown in FIG. 4, even if there is a gap between the light beads 100, the reflective sheet arranged on the light beads 100 can reflect and utilize the emitted light. This can improve the light utilization efficiency of the light beads 100 to some extent and maintain a consistent light intensity across different regions of the light plate 200. Meanwhile, the reflective sheet may be made of a foamed material, which can be composed of raw materials such as plastics (e.g., PE, EVA) or rubbers (e.g., SBR, CR), combined with catalysts, foam stabilizers, foaming agents, and other auxiliary materials. It may be formed through physical foaming or cross-linked foaming into a soft foamed material. Alternatively, it can be a structural foamed material based on plastics (e.g., PVC, PET), modified by a penetrated aromatic amide polymer network. There are pores and gaps within the foamed material, allowing the reflective sheet to better provide resistance to the light bead 100 during its descent. This enhances the stability of the light bead 100 during the mass transfer process and improves the mounting accuracy of the light bead 100.

Furthermore, in order to further improve the mounting accuracy of the light bead 100 during installation, a counterweight portion 111 is further arranged within the light bead main body 110. The counterweight portion 111 is disposed between the first end 610 and the second end 620. The mass of the counterweight portion 111 near the outer side of the light bead main body 110 is greater than the mass near the center of the light bead main body 110. The counterweight portion 111 arranged in this manner ensures that the center of gravity of the light bead 100 remains at the center position of the light bead 100 throughout the mass transfer process, preventing rotation or flipping during the descent caused by shifts in the center of gravity. Furthermore, with the counterweight portion 111 in place, under the combined action of the counterweight portion 111 and the buffer portion 120, the light bead 100 can accurately land on the predetermined position on the light plate 200, preventing misalignment and tilting issues.

As shown in FIG. 2, in order for the light bead 100 to meet the lighting requirements, the light bead 100 further includes a light-emitting chip 160 and a color filter layer 170. The light-emitting chip 160 is disposed within the light bead main body 110. The color filter layer 170 is arranged on the side of the light-emitting chip 160 near the first end 610 of the light bead main body 110. The light emitted by the light-emitting chip 160 passes through the color filter layer 170 to form light of the same or different colors. The color filter layer 170 includes a first color region 171, a second color region 172, and a third color region 173, all having the same area. The light emitted by the light-emitting chip 160 is converted into first color light when passing through the first color region 171. The light emitted by the light-emitting chip 160 is converted into second color light when passing through the second color region 172. The light emitted by the light-emitting chip 160 is converted into third color light when passing through the third color region 173. In this embodiment, the first color light may be red light, the second color light may be green light, and the third color light may be blue light. Of course, the first, second, and third color lights can be combined to form the same color or displayed in different colors. Specifically, the color filter layer 170 may be a quantum dot layer (QD layer) or a phosphor layer used for color conversion. Furthermore, the light-emitting chip 160 can be arranged in the central region of the light bead main body 110 so that the light emitted by the chip is evenly distributed across the first, second, and third color regions 171, 172, and 173 of the color filter layer 170, thereby making the light intensities emitted from these regions nearly uniform. In this embodiment, the counterweight portion 111 is disposed around the periphery of the light-emitting chip 160.

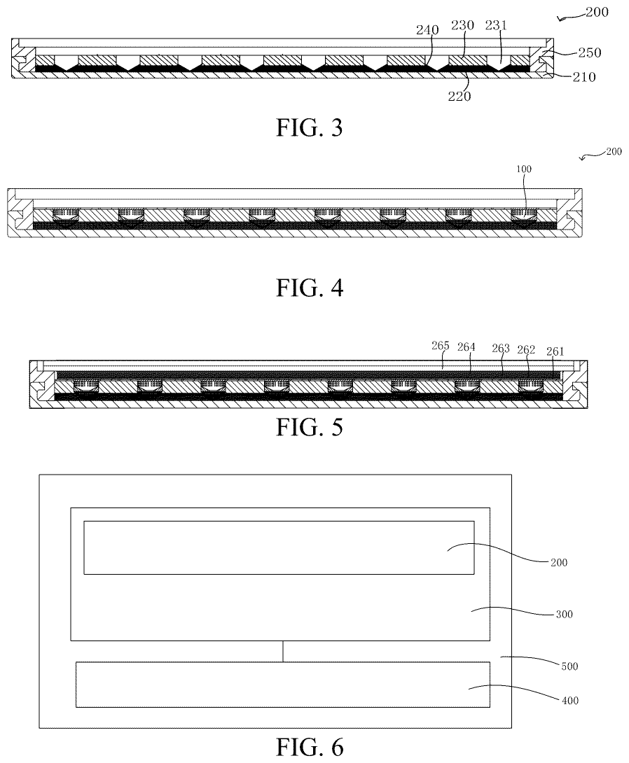

An electrode layer 140 is further disposed on the second end 620 of the light bead main body 110. The electrode layer 140 is connected to the light plate 200. After the light bead 100 is installed onto the light plate 200, the light plate 200 supplies power to the light bead 100 via the electrode layer 140, thereby controlling the light bead 100 to emit light. The second end 620 of the light bead 100 has a conical shape. The electrode layer 140 covers the second end 620 of the light bead main body 110. The light plate 200 includes a power supply layer 240 corresponding to the electrode layer 140 (as shown in FIG. 3). When the light bead 100 is installed on the light plate 200, the electrode layer 140 is connected to the power supply layer 240 to facilitate the light plate 200 in supplying power to the light bead 100.

As shown in FIG. 1, the light bead 100 further comprises an encapsulation layer 180, which is disposed on the side of the color filter layer 170 facing away from the light-emitting chip 160. The encapsulation layer 180 covers the color filter layer 170 to protect it. The buffer portion 120 is disposed on the side of the encapsulation layer 180 facing away from the center of the light bead main body 110, so as not to affect the light emission of the light bead 100. The light bead 100 further includes a grounding pillar 150, which is disposed on the second end 620 of the light bead main body 110. The grounding pillar 150 is connected to the grounding terminal of the light plate 200. The grounding pillar 150 is used for grounding, so that static electricity generated on the light bead 100 can be discharged to the light plate 200 through the grounding pillar 150, thereby protecting the light bead 100 from electrostatic breakdown. To prevent the grounding pillar 150 from breaking due to premature contact with the light plate 200 during mass transfer of the light bead 100, the light bead 100 is further provided with an elastic piece. The elastic piece is disposed on the end of the grounding pillar 150 near the light-emitting chip 160. In this way, even if the grounding pillar 150 comes into contact with the light plate 200 first during the mass transfer process, the elastic piece can elastically deform and compress under the pressure from the grounding pillar 150, thereby preventing the grounding pillar 150 from breaking. It should be noted that the grounding pillar 150 and the elastic piece only need to be configured such that the elastic piece undergoes elastic deformation upon being compressed by the grounding pillar 150. Specific designs may be implemented by the skilled artisan as appropriate, and will not be further detailed herein.

As shown in FIGS. 3 and 4, as a second embodiment of the present application, a light plate 200 is disclosed. The light plate 200 is applied to a display panel 300. The light plate 200 includes a bottom plate 210, a magnetic attraction layer 220, a planarization layer 230, a power supply layer 240, and the light bead 100 as described in the above embodiment. The magnetic attraction layer 220 is disposed on the bottom plate 210. The planarization layer 230 is disposed on the magnetic attraction layer 220. A plurality of mounting slots 231 are disposed on the planarization layer 230 and the magnetic attraction layer 220. The power supply layer 240 is disposed at a bottom of the mounting slot 231. Each of the light beads 100 is mounted in a corresponding mounting slot 231. The power supply layer 240 supplies power to the light bead 100. When the light beads 100 are mounted on the light plate 200, the structure of the light plate 200 is as shown in FIG. 4.

During installation, each light bead 100 is positioned above the corresponding mounting slot 231 on the light plate 200, and the mass transfer installation of the light bead 100 is completed by the weight of the light bead 100 itself. Under the action of the buffer portion 120, a resistance is provided to the light bead 100 during its descent, so as to prevent the light bead 100 from rotating or flipping during the fall, which would otherwise affect the mounting accuracy. This enables precise alignment of the light bead 100, allowing it to be accurately mounted into the corresponding mounting slot 231 in the light plate 200 to complete the mass transfer installation, thereby facilitating the next installation step and improving the efficiency of the mass transfer process to a certain extent.

As shown in FIG. 5, the light plate 200 further includes a lower diffusion layer 261, a lower prism layer 262, an upper prism layer 263, and an upper diffusion layer 264. The lower diffusion layer 261 is disposed on the light bead 100. The lower prism layer 262 is disposed on a side of the lower diffusion layer 261 facing away from the light bead 100. The upper prism layer 263 is disposed on a side of the lower prism layer 262 facing away from the lower diffusion layer 261. The upper diffusion layer 264 is disposed on a side of the upper prism layer 263 facing away from the lower prism layer 262. After the light beads 100 are installed onto the light plate 200 via mass transfer, and after all light beads 100 have been mounted, the lower diffusion layer 261, the lower prism layer 262, the upper prism layer 263, and the upper diffusion layer 264 are sequentially installed onto the light plate 200 to complete the assembly of the light plate 200. The light emitted by the light bead 100 is diffused by the lower diffusion layer 261 and then enters the lower prism layer 262 and the upper prism layer 263. The lower prism layer 262 and the upper prism layer 263 refract part of the light toward the light bead 100, which is then reflected again by the buffer portion 120 made of a reflective sheet and emitted in a direction facing away from the light bead 100, such that under the effect of the lower diffusion layer 261, the lower prism layer 262, the upper prism layer 263, the upper diffusion layer 264, and the buffer portion 120 made of a reflective sheet, the light intensity emitted from various regions of the light plate 200 tends to be uniform. The light plate 200 further includes a glass substrate 265, which is disposed on the end of the upper diffusion layer 264 facing away from the upper prism layer 263. The glass substrate 265 protects the structures within the light plate 200. Furthermore, as shown in FIG. 3, the light plate 200 further includes a sealant frame 250, which is disposed on the bottom plate 210 and located at the periphery of the bottom plate 210. One end of the bottom plate 210 is bent to cooperate with the sealant frame 250, forming the structure shown in FIG. 3. The inventor(s) of the present application has determined through experiments that the bottom plate 210 and the sealant frame 250 configured in this structure have strong bending resistance. That is, when subjected to external forces of the same magnitude, this structure exhibits less deformation, thereby improving the overall stability of the light plate 200 and making it less prone to deformation or damage during the installation of the light beads 100 onto the light plate 200.

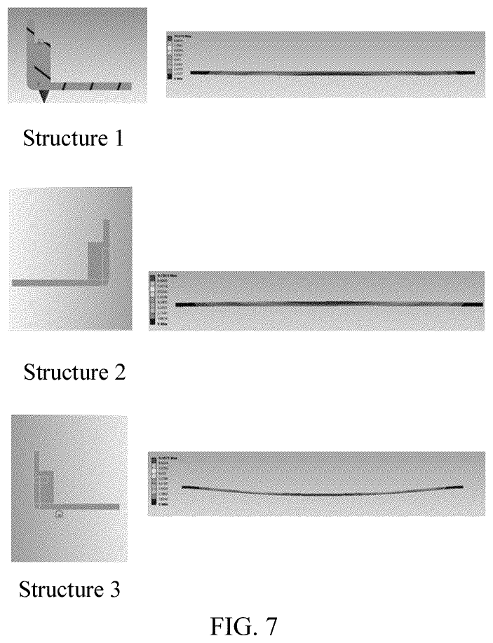

As shown in the simulation results of FIG. 7, the inventor(s) of the present application conducted a comparison of three structural configurations. The shape of the bottom plate 210 and the sealant frame 250 in the present scheme corresponds to Structure Three. In Structure One, the bottom plate 210 and the sealant frame 250 are joined together, where the bottom plate 210 is a straight plate directly connected to the sealant frame 250. Under a load equivalent to a weight of 25 kilograms, the maximum deformation in Structure One is 10.015 millimeters. In Structure Two, the bottom plate 210 is configured in an L-shape with a horizontal plate and a vertical plate, and the vertical plate is joined to the sealant frame 250. Under a load equivalent to a weight of 25 kilograms, the maximum deformation in Structure Two is 9.7863 millimeters. In Structure Three, the bottom plate 210 is designed in a barb shape, and the sealant frame 250 is provided with a groove to match the bottom plate 210, which is joined to the sealant frame 250 to form Structure Three. Under a load equivalent to a weight of 25 kilograms, the maximum deformation in Structure Three is 9.4875 millimeters. Based on the above experimental results, Structure Three exhibits the smallest deformation under a 25-kilogram load, indicating that the bottom plate 210 undergoes minimal deformation and that the overall stability of the light plate 200 is enhanced, making it less prone to deformation. During the installation of the light beads 100 onto the light plate 200, the light plate 200 is thus less likely to be damaged.

As shown in FIG. 6, as a third embodiment of the present application, a display device 500 is disclosed. The display device 500 includes a display panel 300 and a driving circuit 400. The display panel 300 includes the light plate 200 as described in the above embodiments. The driving circuit 400 is configured to drive the display panel 300. In the display panel of this embodiment, a buffer portion is disposed on the light bead. The buffer portion provides resistance during the downward movement of the light bead, enhancing the stability of the light bead during the mass transfer process. This better resists external disturbances during mass transfer and prevents the light bead from rotating or flipping during its descent, which could otherwise affect installation accuracy. It enables precise alignment of the light bead during mass transfer, thereby improving the efficiency of mass transfer and enhancing the installation efficiency of the display device.

It should be noted that the limitations of the various steps involved in this solution are not to be interpreted to limit the order of the steps, under the premise of not affecting the implementation of the specific solution. The steps written earlier can be executed first, or later, or even at the same time as the steps written later. As long as this solution can be implemented, it should be regarded as falling in the scope of protection of this application.

It should be noted that the inventive concept of the present application can be formed into many embodiments, but the length of the application document is limited and so these embodiments cannot be enumerated one by one. Therefore, should no conflict be present, the various embodiments or technical features described above can be arbitrarily combined to form new embodiments. After the various embodiments or technical features are combined, the original technical effects may be enhanced.

The foregoing is a further detailed description of the present application with reference to some specific optional implementations, but it cannot be determined that the specific implementation of the present application is limited to these implementations. For those having ordinary skill in the technical field to which the present application pertains, several deductions or substitutions may be made without departing from the concept of the present application, and all these deductions or substitutions should be regarded as falling within the scope of protection of the present application.

What is claimed is:

1. A light bead applied to a light plate, the light bead comprising:
a light bead main body, the light bead main body comprising a first end and a second end spaced apart from each other, wherein the first end is adjacent to a light-emitting side of the light bead main body, and wherein the second end is opposite to the light-emitting side of the light bead main body;
a buffer portion, disposed on the first end of the light bead main body, the buffer portion fitting around the first end of the light bead main body; and
a mating portion, disposed on the second end of the light bead main body and configured to mate with the light plate to install the light bead onto the light plate;
wherein during installation, the buffer portion is configured to provide a resistance to the light bead to enable the light bead to be installed at a corresponding position on the light plate.

2. The light bead as recited in claim 1, wherein the buffer portion is a reflective sheet fitting around the first end of the light bead main body.

3. The light bead as recited in claim 1, wherein the light bead main body further comprises a counterweight portion arranged between the first end and the second end; wherein a mass of a portion of the counterweight portion closer to an outer side of the light bead main body is greater than a mass of a portion of the counterweight portion closer to a center of the light bead main body.

4. The light bead as recited in claim 1, further comprising an electrode layer disposed on the second end of the light bead main body, the electrode layer being configured to be connected to the light plate.

5. The light bead as recited in claim 1, further comprising a grounding pillar arranged on the second end of the light bead main body.

6. The light bead as recited in claim 1, further comprising a light-emitting chip and a color filter layer, wherein the light-emitting chip is arranged inside the light bead main body, and wherein the color filter layer is arranged on a side of the light-emitting chip facing towards the first end of the light bead main body; wherein light emitted by the light-emitting chip is operative to pass through the color filter layer to form light of the same or different colors;
wherein the color filter layer comprises a first color region, a second color region, and a third color region having an equal area; wherein the light emitted by the light-emitting chip is operative to be converted to first color light after passing through the first color region, converted to second color light after passing through the second color region, and converted to third color light after passing through the third color region.

7. The light bead as recited in claim 6, further comprising an encapsulation layer, which is arranged on the side of a color filter layer facing away from the light-emitting chip, and wherein the buffer portion is arranged on a side of the encapsulation layer facing away from a center of the light bead main body.

8. The light bead as recited in claim 1, wherein the mating portion is a magnetic attraction structure, and wherein the light plate further comprises a magnetic attraction layer disposed corresponding to the mating portion.

9. The light bead as recited in claim 2, wherein the reflective sheet is made of a foamed material.

10. The light bead as recited in claim 6, wherein the color filter layer is a quantum dot layer or a phosphor layer.

11. The light bead as recited in claim 6, wherein the light-emitting chip is disposed in a central region of the light bead main body.

12. The light bead as recited in claim 6, wherein the counterweight portion is arranged around the light-emitting chip.

13. A light plate applied to a display panel, the light plate comprising:
a bottom plate;
a magnetic attraction layer, arranged on the bottom plate;
a planarization layer, arranged on the magnetic attraction layer, wherein there are formed a plurality of mounting slots in the planarization layer and the magnetic attraction layer;
a power supply layer, arranged at a bottom of each of the plurality of mounting slots; and
a plurality of light beads, respectively mounted in the plurality of mounting slots, wherein each of the plurality of light beads comprises a light bead main body, a buffer portion, and a mating portion; wherein the light bead main body comprises a first end and a second end spaced apart from each other, the first end being an end of the light bead main body adjacent to a light-emitting side, the second end being an end of the light bead main body opposite to the light-emitting side of the light bead main body; wherein the buffer portion is arranged on the first end of the light bead main body and is disposed to fit around the first end of the light bead main body; wherein the mating portion is arranged on the second end of the light bead main body and is configured to mate with the light plate to install the light bead onto the light plate;
wherein when each of the plurality of light beads is installed in a respective mounting slot, the respective power supply layer is configured to supply power to the light bead.

14. The light plate as recited in claim 13, further comprising a lower diffusion layer, a lower prism layer, an upper prism layer, and an upper diffusion layer; wherein the lower diffusion layer is arranged on the plurality of light beads; the upper prism layer is arranged on a side of the lower prism layer facing away from the lower diffusion layer; and the upper diffusion layer is arranged on a side of the upper prism layer facing away from the lower prism layer.

15. The light plate as recited in claim 14, further comprising a glass substrate, which is arranged at an end of the upper diffusion layer facing away from the upper prism layer.

16. The light plate as recited in claim 13, further comprising a sealant frame, which is arranged on the bottom plate and disposed at a periphery of the bottom plate.

17. The light plate as recited in claim 13, wherein the buffer portion is a reflective sheet disposed to fit around the first end of the light bead main body.

18. The light plate as recited in claim 13, wherein there is further disposed a counterweight portion inside the light bead main body, the counterweight portion being arranged between the first end and the second end; wherein a mass of a portion of the counterweight portion closer to an outer side of the light bead main body is greater than a mass of a portion of the counterweight portion closer to a center of the light bead main body.

19. The light plate as recited in claim 13, wherein there is further disposed an electrode layer on the second end of the light bead main body, the electrode layer being configured to be connected to the light plate.

20. A display device, comprising a display panel and a driving circuit, wherein the display panel comprises a light plate, the light plate comprising:
a bottom plate;
a magnetic attraction layer, arranged on the bottom plate;
a planarization layer, arranged on the magnetic attraction layer, wherein there are formed a plurality of mounting slots in the planarization layer and the magnetic attraction layer;
a power supply layer, arranged at a bottom of each of the plurality of mounting slots; and
a plurality of light beads, respectively mounted in the plurality of mounting slots, wherein each of the plurality of light beads comprises a light bead main body, a buffer portion, and a mating portion; wherein the light bead main body comprises a first end and a second end spaced apart from each other, the first end being an end of the light bead main body adjacent to a light-emitting side, the second end being an end of the light bead main body opposite to the light-emitting side; wherein the buffer portion is arranged on the first end of the light bead main body and is disposed to fit around the first end of the light bead main body; wherein the mating portion is arranged on the second end of the light bead main body and is configured to mate with the light plate to install the light bead onto the light plate;
wherein when each of the plurality of light beads is installed in a respective mounting slot, the respective power supply layer is configured to supply power to the light bead.
